(19) United States
(12) Patent Application Publication
(10) Pub. No.: US 2006/0065853 A1
(43) Pub. Date: Mar. 30, 2006

(54) APPARATUS AND METHOD FOR MANIPULATING SAMPLE TEMPERATURE FOR FOCUSED ION BEAM PROCESSING

(76) Inventors: Chad Rue, Poughkeepsie, NY (US); Steven B. Herschbein, Hopewell Junction, NY (US); Carmelo F. Scrudato, Ossining, NY (US); Lawrence S. Fischer, Poughkeepsie, NY (US)

Correspondence Address: CANTOR COLBURN LLP, 55 GRIFFIN ROAD SOUTH, BLOOMFIELD, CT, 06002, US

(21) Appl. No.: 10/711,691

(22) Filed: Sep. 30, 2004

(51) Int. Cl. H01J 37/317

(52) U.S. Cl. 250/492.21; 250/443.1

(57) ABSTRACT

An apparatus for manipulating the temperature of a sample used in focused ion beam FIB processing includes a base member, a thermoelectric module disposed over the base member, and a sample mounted on a mounting surface of the thermoelectric module. The thermoelectric module is configured so as to reduce the temperature of the sample with respect to an ambient FIB tool temperature.

### BACKGROUND OF INVENTION

The present invention relates generally to focused ion beam (FIB) processing techniques in semiconductor device manufacturing, and, more particularly, to an apparatus and method for manipulating sample temperature for FIB processing.

Focused ion beam (FIB) systems are widely used in microscopic-scale manufacturing operations because of their ability to image, etch, mill, deposit, and analyze with great precision. Because of their versatility and precision, FIB systems have particularly gained widespread acceptance in the integrated circuit (IC) industry as analytical tools for use in process development, failure analysis, and defect characterization.

During FIB processing, an ion beam is used to either locally deposit or remove materials. The ion beam can be rastered over specific areas of the sample to sputter material from the surface. Additionally, the ion beam can be used in conjunction with a flow of gas molecules to enhance etching or to perform depositions (depending on the nature of the gas used). A variety of ion beam sources may be employed in the FIB, including liquid metal ion sources or gas field ion sources. Both of these sources have a needle type form that relies on field ionization or evaporation to produce the ion beam. Modern state-of-the-art FIB tools equipped with liquid metal ion sources generally have superior resolution, and are capable of generating beams with a focused spot size on the order of 50 nm.

Once the ion beam is produced, it is deflected in a vacuum and directed to a desired surface area. A gaseous material is often directed to the sample at the impact point of the ion beam, and the energy of the ion beam causes the adsorbed gas molecules to decompose. These decomposed species can promote either etching or film growth, depending on the gaseous compound that is used. Focused ion beams are particularly suitable in the semiconductor processing industry as a cutting or depositing tool for performing a circuit repair, mask repair or micro-machining process.

Notwithstanding the beneficial aspects of FIB technology, certain process parameters for operations such as gas-assisted etching (GAE) (i.e., milling) and material deposition using FIB tools should be carefully controlled for desired results. For example, during a GAE process, the sample surface is flooded with vapors of a chemical etchant (e.g., typically halogenated compounds such as chlorine, bromine, or xenon difluoride). These molecules by themselves usually exhibit little to no reactivity towards the sample at room temperature. However, when the FIB ion beam is rastered over the sample surface, the precursor molecules adsorbed on the surface decompose, producing highly reactive species (e.g., Cl, Br, or F radicals) that accelerate the milling rate. The rate of material removal during a GAE process may be several times higher than the rate of a straight sputtering mill.

Efficient GAE performance thus requires a careful balance of precursor gas concentration and beam intensity. If the gas flux is too low for a given beam current, the precursor will be rapidly consumed (a process referred to as “out-running the gas”), and the process will take on the characteristics of a simple straight sputtering mill. As such, it is desirable to maximize the GAE precursor concentration on the sample in order to maintain an efficient chemically assisted mill.

With regard to material deposition, the sample can also be flooded with vapors of metal-bearing molecules, such as tungsten hexacarbonyl, for example. In addition, various organometallic compounds of platinum, chromium, gold, titanium, copper and nickel are also relatively common. Decomposition of the precursor compound leads to the accumulation of a metal-rich film, which can be used to deposit fine wires for electrical contacts. During a deposition process (perhaps even more so than for GAE processes), the precursor concentration on the surface must be kept high enough to accommodate the intensity of the ion beam. If the gas becomes depleted, the ion beam will actually sputter away any metal film that was previously deposited.

In addition to metal depositions, an FIB process can also be used to deposit insulating films by flooding the surface with a silicon-bearing precursor and an oxidizing agent such as O₂ or H₂O. TEOS (tetraethylorthosilicate) and TMCTS (tetramethylcyclotetrasiloxane) are common silicon-bearing precursors used for this purpose.

As the feature sizes in modern integrated circuits (ICs) have become smaller, FIB manufacturers have introduced FIBs with higher resolution. This has previously been accomplished by increasing the acceleration energy of the ions and by redesigning the electrostatic focusing assembly to form a more tightly confined beam. The end result is an ion beam with very high current density. However, this presents another challenge when performing GAE or deposition work, as these increased intensity ion beams are more likely to outrun the precursor gas on the surface. This effect can be partially offset by intentionally defocusing the beam (i.e., making the center of the beam spot more diffuse), but this negates the benefits of a higher resolution ion beam. It is thus preferable to maximize the gas concentration on the surface as much as possible. One option in this regard is to simply increase the pressure of the precursor gas; however, this approach is limited by the pumping constraints of the FIB vacuum system.

Accordingly, it would be desirable to be able to effectively improve the precursor surface concentration so as to improve overall FIB processing efficiency in a manner that is easily adaptable to existing FIB equipment.

### SUMMARY OF INVENTION

The foregoing discussed drawbacks and deficiencies of the prior art are overcome or alleviated by an apparatus for manipulating the temperature of a sample used in focused ion beam FIB processing. In an exemplary embodiment, the apparatus includes a base member, a thermoelectric module disposed over the base member, and a sample mounted on a mounting surface of the thermoelectric module. The thermoelectric module is configured so as to reduce the temperature of the sample with respect to an ambient FIB tool temperature.

In another embodiment, a method for implementing focused ion beam (FIB) processing includes mounting a sample on a mounting surface of an FIB tool, the mounting surface including a thermoelectric element. The thermoelectric element is controlled so as to reduce the temperature of the sample with respect to an ambient FIB tool temperature, and an FIB is applied to the sample.

### BRIEF DESCRIPTION OF DRAWINGS

Referring to the exemplary drawings wherein like elements are numbered alike in the several Figures:

FIG. 1 is a graph illustrating the rate of silicon removal for a sample, as a function of temperature, with a focused ion beam process using an Xe F2 percursor;

FIG. 2 is a graph illustrating increasing film thickness of an SiO₂ insulating film with decreasing FIB sample temperature;

FIG. 3 is a graph illustrating decreasing resistance of an FIB-deposited tungsten layer with decreasing sample temperature;

FIG. 4(a) is a cross sectional image of a layer of tungsten deposited by FIB at a temperature of about 57° C., resulting in a measured layer resistance of about 1650 ohms (Ω);

FIG. 4(b) a cross sectional image of another layer of tungsten deposited by FIB deposition at a reduced temperature of about 30° C., resulting in a decreased measured layer resistance of about 520 Ω;

FIG. 4(c) a cross sectional image of still another layer of tungsten deposited by FIB deposition at a further reduced temperature of about 1° C., resulting in a decreased measured layer resistance of about 380 Ω;

FIG. 5 is a schematic diagram illustrating an apparatus for manipulating sample temperature for FIB processing, in accordance with an embodiment of the invention;

FIG. 6 is a schematic diagram illustrating an alternative embodiment of the apparatus shown in FIG. 5; and

FIG. 7 is a schematic diagram illustrating still an alternative embodiment of the apparatus shown in FIG. 5.

### DETAILED DESCRIPTION

Disclosed herein is an apparatus and method for manipulating sample temperature for FIB processing in which a physical cooling scheme (in one embodiment) is implemented in order to manipulate sample temperature during FIB processing for improved process efficiency. Moreover, through the use of a thermoelectric (Peltier effect) device in contact with the FIB sample, existing electrical connections of a conventional commercial FIB apparatus are relatively easily modified to accommodate the additional electrical inputs used to control the thermoelectric device. As opposed to a more traditional cooling scheme, such as by circulating a cooling fluid, the present approach does not require extensive hardware modifications that may increase the difficulty in maintaining vacuum integrity of the system. In addition, a thermoelectric approach avoids vibration and drag on the laser interferometer stage induced by flex cooling lines.

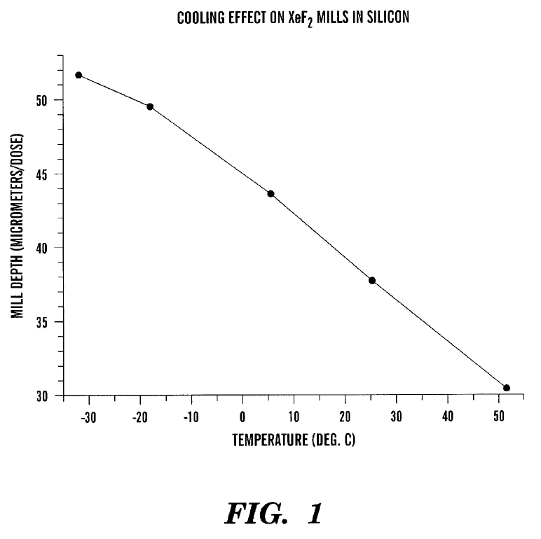

The embodiments described hereinafter make advantageous use of the discovery that certain (FIB) processes are temperature dependent and, as such, can be optimized by adjusting the sample temperature. More specifically, it has been determined that low sample temperatures (with respect to an ambient FIB tool temperature) lead to higher yield for FIB metal depositions using metal beta-diketonate precursors. It has further been determined that temperature control has a significant impact on both xenon difluoride (XeF₂) milling of silicon, as well as on tungsten depositions using W(CO)₆ as a precursor. For example, FIG. 1 is a graph illustrating the rate of silicon removal using XeF₂ as a function of temperature. As is shown, the mill depth is increased as sample temperature decreases.

In addition to the results shown in FIG. 1, it is also expected that other material removal processes may be enhanced at lower sample temperatures including, but not limited to: XeF₂ mills of SiO₂, XeF₂ mills of tungsten, Br₂ mills of silicon, Br₂ mills of aluminum, XeF₂ mills of SiCOH type low-k dielectric materials, XeF₂ mills of chromium (e.g., for mask repair), XeF₂ mills of organic materials and polymers (e.g., SiLK low-k dielectric, polyimide, photoresist, etc.), and XeF₂ mills of copper.

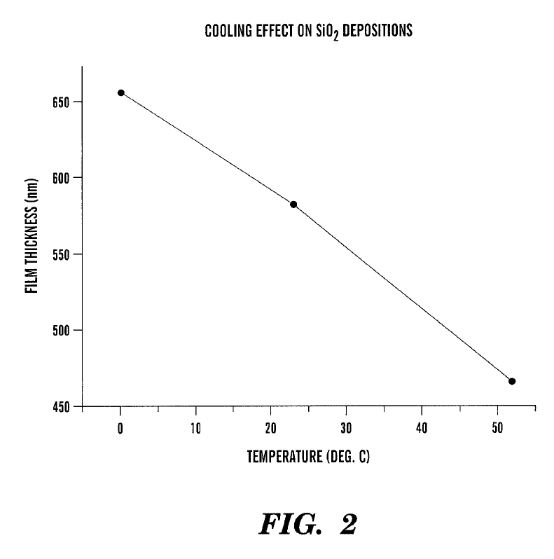

Similarly, for an additive process, the graph of FIG. 2 illustrates that the film thickness of an SiO₂ insulating film increases with decreasing sample temperature using a tetramethylcyclotetrasiloxane (TMCTS) precursor. FIB SiO₂ depositions generally use TMCTS or tetraethylorthosilicate (TEOS) together with an oxidizing agent (e.g., O₂) to help achieve the proper stoichiometry. Thus, various precursor combinations that may be enhanced at low sample temperatures include, but are not limited to: TMCTS (with no oxidizing agent), TMCTS+O₂, TMCTS+H₂O, TEOS (with no oxidizing agent), TEOS+O₂, and TEOS+H₂O. Other silicon-bearing precursors are also contemplated, however.

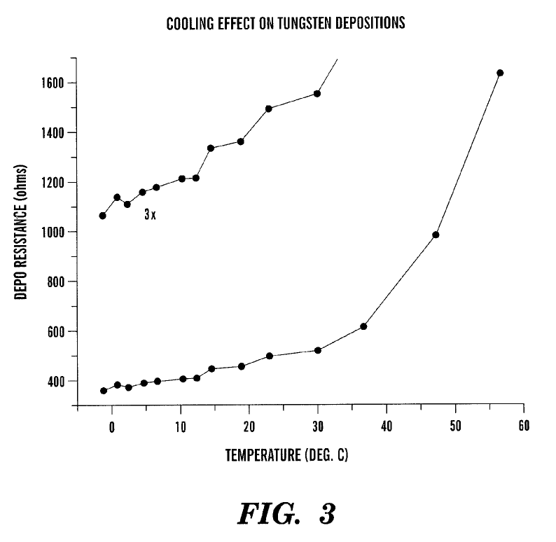

The beneficial low temperature performance also applies for metallic (e.g., tungsten) depositions using a tungsten hexacarbonyl (W(CO)₆) precursor, a common metal deposition precursor available in existing commercial FIB systems. Other metal precursors are also contemplated, including, but not limited to: methylcyclopentadienyl (trimethyl) platinum (V), any of the beta-diketonate copper (II) complexes, such as bis(hexafluoroacetylacetonate) copper(II), and any of the “Lewis-base” copper (I) beta-diketonate complexes, such as (hexafluoroacetylacetonate) (vinyltrimethylsilane) copper(I). As shown in the graph of FIG. 3, the resistance of the deposited tungsten layer decreases with decreasing sample temperature, thus indicating a higher overall tungsten yield for the deposition performed at the cooler temperature. This in turn results in a lower resistance.

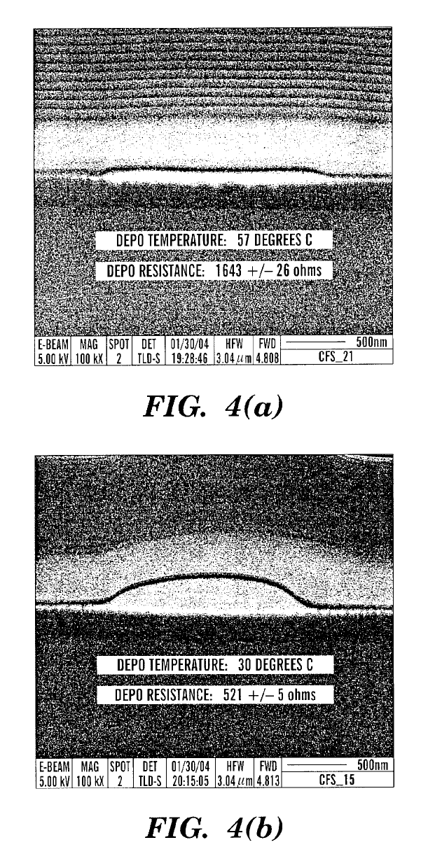

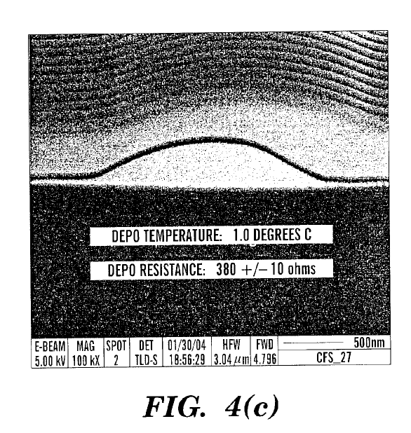

FIGS. 4(a) through 4(c) depict cross sectional images of tungsten depositions performed at various temperatures, in order to demonstrate an increasing accumulation of material (and hence a lower electrical resistances) at lower temperatures. In all cases, the physical dimensions of the depositions were 100 μm long by 1 μm wide, and the total beam exposure during each experiment was 2 nano-Coulombs/μm². In FIG. 4(a), the cross sectional image of a layer of tungsten deposited at a temperature of about 57° C. resulted in a measured layer resistance of about 1650 ohms (Ω). In contrast, the FIB deposition of tungsten at a reduced temperature of about 30° C. resulted in a decreased measured layer resistance of about 520 Ω, as shown in FIG. 4(b). As shown in the image of FIG. 4(c), a further reduction in deposition temperature to about 1° C. resulted in even lower measured layer resistance of about 380 Ω.

It will thus be appreciated that the increased rate of silicon removal using XeF₂ and the increased rate of tungsten deposition using a W(CO)₆ precursor leads to shorter process times and more reliable performance over a wider range of conditions. These findings are perhaps somewhat counter-intuitive, since most chemical processes are accelerated at higher temperatures. One possible explanation for the findings is that lower temperatures lead to increased gas adsorption/decreased desorption, which thus increases the surface concentration of precursor molecules (e.g., XeF₂ for etching and W(CO)₆ for metal depositions).

The ability to perform specific GAE or deposition processes more efficiently (due to the sample cooling process) may be beneficial when working with modern IC or photomask devices that are negatively affected by prolonged exposure to the FIB beam. For example, silicon-on-insulator (SOI) IC devices are particularly susceptible to beam-induced charge damage. By maximizing the efficiency of gas processes, one can minimize the duration of their exposure to the beam during necessary FIB modifications, thereby minimizing the risk of charge-induced damage from the FIB beam. In mask repair, the ion beam can cause staining of the quartz substrate, which affects optical transparency. This can also be minimized if GAE processes are optimized through sample cooling.

In failure-analysis applications, the FIB is often used to make discrete electrical contacts to the various nodes of individual SRAM memory cells for electrical analysis. However, the implanted gallium ions from the FIB beam can alter the doping of the active areas and perturb the operating voltages of the cell's transistors. Thus, minimizing FIB beam exposure by optimizing the necessary gas processes would be beneficial in minimizing the impact of the FIB work, so that the actual electrical characteristics of the target electrical structure can be assessed.

In any case, conventional commercial FIBs heretofore have not incorporated sample temperature control features, presumably because the benefits of sample temperature control were not previously appreciated and/or because there are certain logistical challenges associated with manipulating the sample temperature inside FIB vacuum chambers.

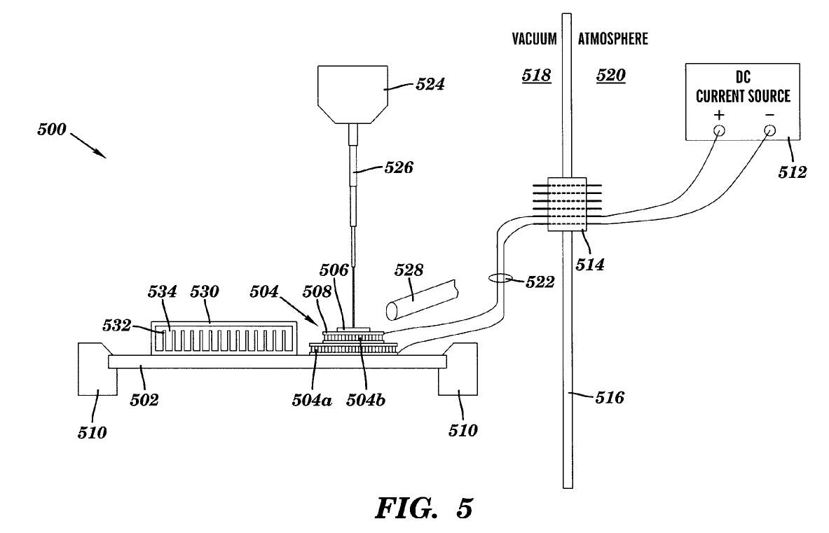

Therefore, in accordance with an embodiment of the invention, FIG. 5 is a schematic diagram illustrating an apparatus 500 for manipulating sample temperature for FIB processing. As is shown, the apparatus 500 includes a base member 502, formed from a material such as of stainless steel, a thermoelectric (TE) module 504 on the base member 502, and a sample 506 mounted on a mounting surface 508 of the TE module 504. The stainless steel base member 502 has a high enough mass (and heat capacity) such that a stable temperature of about −20° C. may be maintained on the mounting surface 508, without using external cooling or a thermal ballast. However, the base member 502 may also be made of a material with a lower heat capacity (but higher thermal conductivity, such as aluminum or copper, for example). Physical contact between the base member 502 and the rest of the FIB apparatus 500 may be maintained by a clamping mechanism 510.

In the example depicted, the thermoelectric module 504 is a heating/cooling device that utilizes a physical principle known as the Peltier effect, by which DC current is applied across two dissimilar materials causing heat to be absorbed at the junction of the two dissimilar materials. Thus, the heat is removed from a hot substance and may be transported to a heat sink to be dissipated, thereby cooling the hot substance. By swapping the polarity of the incoming voltage, the TE module 504 can also switch from cooling to heating mode. In cooling mode, heat is drawn from the sample 506 by the TE module 504 and exhausted to the base member 502. The exemplary TE module 504 depicted in FIG. 5 includes a stacked (serial) pair of individual Peltier elements 504a, 504b, which allows for lower absolute temperatures to be attained, as compared to a single Peltier element. Other configurations are also contemplated, however, including (for example) a single Peltier element, three or more stacked Peltier elements, or multiple Peltier elements configured in parallel (e.g., for large samples or in cases where the heat load is very high).

Advantageously, the operating DC current supply 512 for the TE Peltier module 504 is supplied through the FIB tool's existing electrical connector 514, disposed through a vacuum chamber wall 516 of the FIB tool. Connector 514 thus provides a flexible, internal electrical interface between the interior vacuum section 518 of the FIB tool and the external atmosphere 520. Flexible wires 522 are inserted into the vacuum side of the connector 514 to route the supply current from source 512 to the TE module 504 on which the sample 506 is mounted, thereby providing the desired temperature control. FIG. 5 further illustrates additional elements of an FIB tool, including an ion source (column) 524, a focused ion beam 526 produced by the ion source 524, and a gas (precursor) delivery nozzle 528.

In situations where physical contact between the FIB apparatus 500 and the base member 502 is inadequate, the base member temperature may rise over time, and as a result the temperature of the sample 506 may become unstable. Therefore, in order to alleviate such a potential, a thermal ballast module 530 may optionally be mounted onto the base member 502, and adjacent to the TE sample mounting surface 508. The thermal ballast module 530 may be a sealed, hollow vessel, constructed from a material with a high thermal conductivity, such copper or aluminum for example, and may also include internal fins 532 for efficient heat transfer from the base member 502 to an internal ballast material 534. The internal ballast material 534 may include a high heat-capacity material, such as water for example, which may be frozen prior to loading the apparatus 500 into the FIB tool, allowing for lower ultimate temperatures. Additionally, the phase change of water would provide a stable base temperature over extended periods of operation.

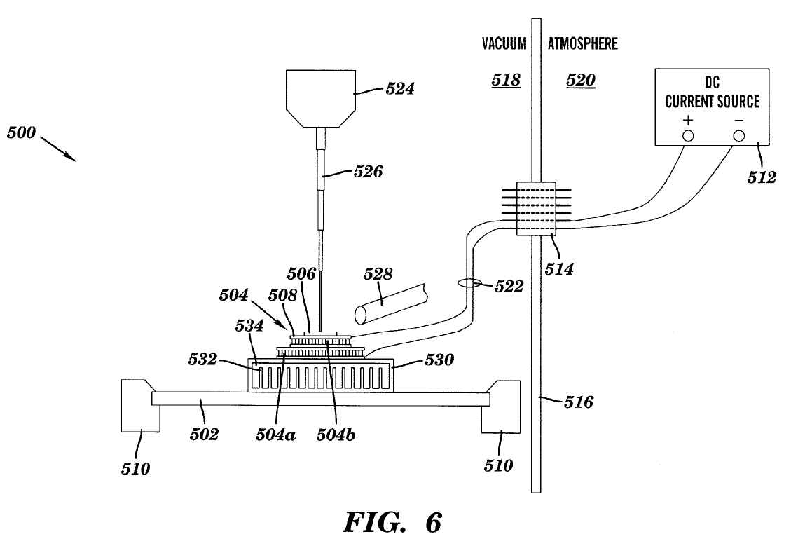

FIG. 6 is an alternative embodiment of FIG. 5, in which the TE module 504 is mounted directly to the thermal ballast module 530. While the embodiment of FIG. 6 may perhaps provide increased heat transfer efficiency with respect to the embodiment of FIG. 5, the internal configuration of components results in somewhat of a taller arrangement of components. This may be a consideration where tool component clearances are at issue.

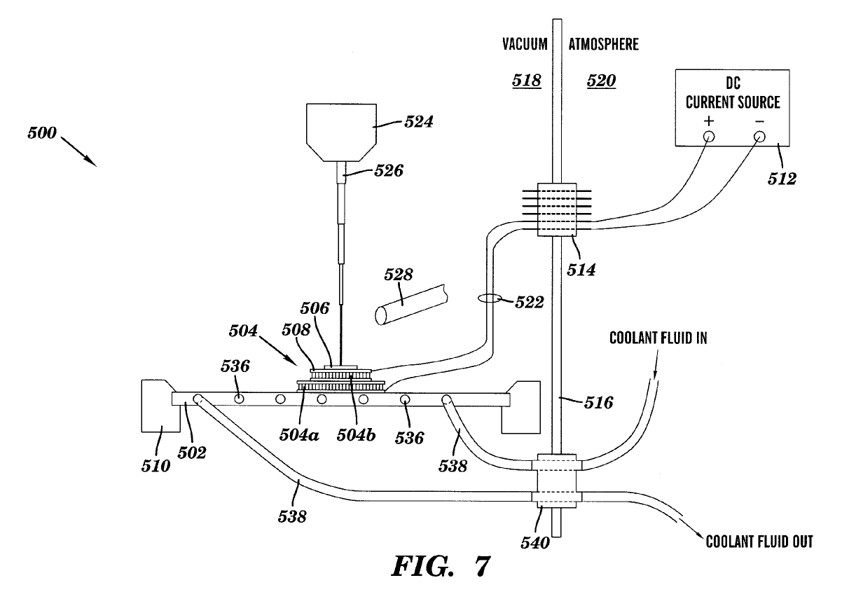

Finally, FIG. 7 is a schematic diagram of still another embodiment of apparatus 500, in which the base member 502 is configured with (in lieu of a thermal ballast module) cooling ports 536 that accommodate cooling lines 538 for circulating a cooling medium through the base member 502. In this embodiment, the cooling lines 538 help exhaust heat from the bottom of the TE module 504, and may provide sufficient cooling as to allow the elimination of the Peltier elements. On the other hand, the use of cooling lines 538 results in additional hardware modifications, specifically in the form of cooling medium connector 540 for routing the cooling lines 538 between the vacuum section 518 and the atmosphere 520.

As will be appreciated, despite the benefits of sample cooling, conventional commercial FIBs have not been previously equipped with sample temperature control functions. Additionally, traditional cooling schemes utilizing circulating fluids would be difficult to implement on a conventional FIB sample holder for at least two reasons. First, a leak-tight fluid connection between the sample holder and the cooling lines would have to be re-established with every load cycle, inside the vacuum chamber and without human intervention. Second, the drag induced by the resulting attached flex lines would hinder the movements of the laser-interferometer stage, making precision targeting of sub-micron features more difficult. In contrast, the present invention embodiments allow a user to control the sample temperature from outside a vacuum chamber, using (in certain embodiments) only electrical signals. Thus, the implementation of cooling recipes may be achieved with minimal hardware modifications.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. An apparatus for manipulating the temperature of a sample used in focused ion beam FIB processing, comprising:
a base member;
a thermoelectric module disposed over the base member; and
a sample mounted on a mounting surface of the thermoelectric module;
wherein said thermoelectric module is configured so as to reduce the temperature of said sample with respect to an ambient FIB tool temperature.

2. The apparatus of claim 1, wherein said thermoelectric module further comprises a Peltier device.

3. The apparatus of claim 2, wherein said thermoelectric module is configured to draw heat from the sample and exhaust said heat through said base member.

4. The apparatus of claim 1, wherein said thermoelectric module is electrically coupled to a current source through an electrical connector disposed through a vacuum chamber wall of an FIB tool.

5. The apparatus of claim 1, further comprising a thermal ballast module mounted on said base member.

6. The apparatus of claim 5, wherein said thermal ballast module is disposed adjacent to said thermoelectric module.

7. The apparatus of claim 5, wherein said thermoelectric module in mounted on said thermal ballast module.

8. The apparatus of claim 5, wherein said thermal ballast module further comprises:
a sealed, hollow vessel constructed from a material having a high thermal conductivity; and
a plurality of internal fins configured for facilitating heat transfer from said base member to an internal ballast material, said internal ballast material including a high heat-capacity material.

9. The apparatus of claim 4, further comprising a plurality of cooling ports within said base member, said cooling ports for receiving a cooling medium circulated therethrough supplied by a cooling supply line.

10. The apparatus of claim 9, wherein said cooling supply line is coupled to a cooling medium connector disposed through a vacuum chamber wall of an FIB tool.

11. A method for implementing focused ion beam (FIB) processing, the method comprising:
mounting a sample on a mounting surface of an FIB tool, said mounting surface including a thermoelectric element;
controlling said thermoelectric element so as to reduce the temperature of said sample with respect to an ambient FIB tool temperature; and
applying an FIB to said sample.

12. The method of claim 11, wherein said thermoelectric element further comprises a Peltier device.

13. The method of claim 11, further comprising utilizing said FIB to deposit a layer on said sample.

14. The method of claim 13, wherein said layer comprises an insulating layer deposited using a silicon-bearing precursor.

15. The method of claim 14, wherein said insulating layer comprises SiO₂.

16. The method of claim 13, wherein said layer comprises an insulating layer deposited using at least one or more of the following precursor combinations: tetramethylcyclotetrasiloxane (TMCTS) with no oxidizing agent, tetraethylorthosilicate (TEOS) with O₂, TMCTS with H₂O, TEOS with O₂, TEOS with O₂, TEOS with H₂O.

17. The method of claim 13, wherein said layer comprises a metal layer deposited using at least one or more of the following precursor combinations: tungsten hexacarbonyl (W(CO)₆), methylcyclopentadienyl (trimethyl) platinum (V), any of the beta-diketonate copper (II) complexes, and any of the Lewis-base copper (I) beta-diketonate complexes.

18. The method of claim 11, further comprising utilizing said FIB in a removal process to remove material from said sample.

19. The method of claim 18, wherein said removal process further comprises at least one of: milling silicon using a xenon difluoride (XeF₂) precursor, milling SiO₂ using an XeF₂ precursor, milling tungsten using an XeF₂ precursor, milling SiCOH type low-k dielectric materials using an XeF₂ precursor, milling chromium using an XeF₂ precursor, milling organic materials and polymers using an XeF₂ precursor, milling copper using an XeF₂ precursor, milling silicon using a Br₂ precursor, and milling aluminum using a Br₂ precursor.
